(19) United States
(12) Patent Application Publication
(10) Pub. No.: US 2012/0107525 A1
(43) Pub. Date: May 3, 2012

(54) CO2 Recycling Method and CO2 Reduction Method and Device

(76) Inventor: Nobuo Ohmae, Hyogo (JP)

(21) Appl. No.: 13/382,881

(22) PCT Filed: Jul. 8, 2010
(86) PCT No.: PCT/JP2010/004463

§ 371 Date: Jan. 6, 2012

(30) Foreign Application Priority Data
Jul. 8, 2009 (JP) 2009-162058

(51) Int. Cl. H05H 1/24; C23C 16/26; B82Y 40/00

(52) U.S. Cl. 427/577; 118/47; 977/841

(57) ABSTRACT

Disclosed is a device which uses CO₂ in exhaust gases as a carbon source and immobilises the carbon (C) in the CO₂ to create an advanced carbon fuel in the form of useful, high added-value nanocarbon structures such as multi-layer carbon-nanotubes, carbon-onions or the like, and which also reduces the quantity of the CO₂ contained in exhaust gases that is emitted into the atmosphere. A reactor is provided with at least: a substrate upon the surface whereof a catalyst layer of iron or the like is formed; a heat source means for heating the substrate; a gas introducing means for introducing carbon oxide containing gas onto the surface of the substrate; a microwave plasma generation means for generating microwave plasma on the surface of the substrate; and a power supply means, for the generation of microwave plasma. The heat source means uses exhaust heat from the front muffler of a car, the power supply means uses an on-board car battery and microwave plasma CVD is used to create multi-layer carbon-nanotubes, carbon-onions or the like on the surface of the substrate, using the CO₂ within car exhaust gases as a carbon source.

### RELATED APPLICATIONS

To the fullest extent possible, the present application claims priority to, and incorporates by reference, PCT/JP2010/004463 filed Jul. 8, 2010 and JP 2009-162058 filed Jul. 8, 2009.

### TECHNICAL FIELD

The present invention includes the solidification of carbon contained in carbon dioxide (CO₂), carbon mono-oxide (CO) and hydrocarbon (HC), which are the exhaustion gases from automobiles and ships, and the consequent reduction of emission of green-house effect gases, and also the synthesis of such value-added advanced nano-carbons as carbon nanotubes (CNT), carbon onion, carbon nano-horns etc.

### BACKGROUND ART

In view of the social significance, emission of CO₂ is one of the biggest issues that our human beings are presently facing.

The decomposition of CO₂ accompanies a lot of difficulties, because the decomposition energy of CO₂, which requires the de-bonding of C and O, is higher than those of carbon mono-oxide (CO) and hydrocarbons (HC). One of the processing methods of CO₂ is the synthesis of carbon nanotube by solidifying carbon. Carbon Nanotube manufacturing method which utilizes the transformation of CO from CO₂ in exhaustion gases and then synthesizes single walled carbon nanotube (SWCNT) with the method of chemical vapor deposition (CVD) is known (Patent Document 1).

The above stated method, however, contains a complicated process for decomposing CO₂ into CO. In addition, the method needs huge facilities and the obtained carbon structure was limited to single walled carbon nanotube (SWCNT).

[Patent Document 1] JP-A-2006-27949

### DISCLOSURE OF THE INVENTION

### Problems to be Solved by the Invention

The aim of this invention is to synthesize such value-added nano carbons by solidifying carbons in CO₂ emitted as exhaust gas from automobiles, ships and combustion facilities as well as to develop the methods and devices which reduce the amount of CO₂ in exhaustion gases.

Here, the term carbon onion is defined to include onion-like carbons.

### Means to Solve the Objects

To solve the above-stated problems, the CO₂ recycling method of this invention aims the synthesis of either or all the multi-walled carbon nanotube, carbon onion and nano-carbons using CO₂ in the carbon oxide gases with microwave plasma enhanced CVD or thermal CVD.

The carbon oxide gases signifies exhaustion gases from automobiles, ships, combustion facilities of heavy industries such as steel-making companies, air conditioning devices of underground and large scale department stores where people gather, air conditioning devices of buildings and apartment houses. In addition, the gases designated in this invention include petroleum, coal and natural gases, converted natural gases, combustion exhaust gases which generate from the coal gas when it is burned by a boiler, for example, in the thermal power station.

The recycling method of this invention is to prevent the emission of CO₂ by synthesizing value-added advanced carbon materials through solidifying CO₂ in carbon-oxide gases.

In particular in the case of automobile exhaustion gas, it is expected to reduce friction in the pistons and improve fuel consumption by adding multi-walled carbon nanotube, carbon onion and other nano-carbons to lubricating engine oil.

Nano-carbons such as carbon onion derived from the present CO₂ recycling method can be transformed into films or dispersed in the liquid. Lubricating oils added with nano-carbons have high lubricity with low friction properties and are superior to well-known poly-alpha olefin (PAO2, PAO30, PAO400).

Coatings of nano-carbons such as carbon onion for the purpose of anti-static electricity and those combined with polymers give low friction and good lubricating ability.

In the above-stated recycling method, hydrogen is suited as a carrier gas for carbon oxide gases. In addition, the pressure at microwave plasma CVD or thermal CVD is suited at 100 to 200 (Pa). Moreover, the suitable reaction temperature at microwave plasma CVD or thermal CVD is 800 to 980 degrees Celsius.

The present recycling method of CO₂ also manufactures multi-walled carbon nanotubes and carbon nano-flakes from carbon mono-oxide gas using the microwave plasma CVD.

It is noted that the present CO₂ reduction method reduces more than 70% of CO₂ in carbon oxide gas.

CO₂ recycling device, the first item in this invention, is equipped with at least

1) substrate coated with such catalysts as Fe etc. at the surface,

2) heating means which heat the substrate,

3) gas introduction means which supplies carbon oxide gases to the substrate,

4) microwave plasma generator means which creates microwave plasma around the substrate, and

5) power supply means which generate microwave plasma.

Heating means described in the above 2) also utilizes exhaust heat from muffler, and power supply means in the above 5) dry buttery of automobiles, and from CO₂ gas in the exhaust gas multi-walled carbon nanotubes, carbon onions and/or nano-carbons are synthesized on the surface of substrate using microwave plasma CVD.

In accordance with the above setting-up, value-added nano-carbon structures such as multi-walled carbon nanotubes, carbon onions are manufactured by solidifying C in CO₂, and also the device reduces the emission of CO₂ to environmental atmosphere. When using battery in the car, there is no requirement for designing a specific power supply.

Next, CO₂ recycling device, the second item in this invention, is equipped with at least

1) substrate on which catalyst such as Fe is coated,

2) heating means in order to heat the substrate,

3) gas introduction means which introduces carbon oxide gases.

The heating means in the above 2) utilizes the heat from front-muffler to synthesize multi-walled carbon nanotubes, carbon onion and/or nano-carbons on the surface of substrate in the above 1) using the thermal CVD.

In accordance with the above setting-up, value-added nano-carbon structures such as multi-walled carbon nanotubes, carbon onions are manufactured by solidifying C in CO₂, and also the device reduces the emission of CO₂ to environmental atmosphere. When using battery in the car, there is no requirement for designing a specific power supply.

It is advantageous that the substrate in the above 1) is placed inside the muffler pipe. By doing so, the gas introduction means of gases will be unnecessary, and the device in this invention can be loaded easily on presently existing automobiles.

The above stated device described in viewpoints 1 and 2 synthesizes such advanced and value-added materials as multi-walled carbon nanotubes and carbon onions by solidifying carbon from CO₂ and reduces CO₂ emission, aiming zero carbon-offset. The device can be placed near the exhaust ducts or filters from air-conditioning of underground stores, buildings, and apartments, ventilation devices of tunnels, ships, steam locomotives, combustion facilities, and near the facilities of express highway and tunnels.

It is advantageous that the heating device of the reactive device described in viewpoints 1 and 2 should have the capability of heating the substrate to 800 to 900 degrees Celsius. As it will be shown later in the section of embodiment, value-added and useful nano-carbons are created at the substrate temperature of 800 to 980 degrees Celsius.

The direction of introducing gas passes through the heating device and enters the microwave plasma, and thus the substrate should be placed within the prescribed distance from the microwave plasma-generator.

As can be seen later in the embodiment 2, the configurations of gas introduction means and substrate effectively create nano-carbon structures.

### Effects of the Invention

The effect of this invention is not only the synthesis of value-added nano-carbons, such as multi-walled carbon nanotubes and carbon onions, by solidifying carbon contained in exhaustion gases of automobiles, but also the reduction of CO₂ emission to environmental atmosphere.

### BRIEF DESCRIPTION OF THE DRAWINGS

FIG. 1 is a schematic drawing of the reaction device utilizing microwave plasma CVD, employed in the embodiment 1.

FIG. 2 is scanning and transmission electron microscope photographs of nano-carbon structure synthesized from exhaust gas using the microwave plasma CVD method.

FIG. 3 is scanning and transmission electron microscope photographs of nano-carbon structure synthesized from exhaust gas using the thermal CVD method.

FIG. 4 is scanning and transmission electron microscope photographs of nano-carbon structure synthesized from CO₂ using the microwave plasma CVD method.

FIG. 5 is transmission electron microscope photograph of nano-carbon structure synthesized from CO₂ using the microwave plasma CVD method.

FIG. 6 is a graph showing lubricating ability of carbon nanotubes.

FIG. 7 is schematic drawing of the reaction device utilizing microwave plasma CVD, employed in the embodiment 2.

FIG. 8 is the difference between the two reaction devices used in the embodiments 1 and 2.

FIG. 9 is the surface of nano-carbon structure formed on substrate by the reaction device used in the embodiment 2.

FIG. 10 is a graph showing the results of density and length of synthesized fibrous deposits.

FIG. 11 is surface appearance of fibrous deposits synthesized at the furnace temperatures of 1073K (800 degrees Celsius), 1123K (850 degrees Celsius) and 1203K (930 degrees Celsius).

FIG. 12 is a TEM photograph of the fibrous deposits removed mechanically from the substrate surface.

FIG. 13 is electron diffraction patterns taken from the rod (b) and chunk (c) in FIG. 12.

FIG. 14 is a graph showing the results of composition measurements of major chemical components (EDS).

FIG. 15 is a graph showing the quantitative analysis.

FIG. 16 is TEM photographs showing the chunk of fibrous deposits synthesized at varied temperatures.

FIG. 17 is TEM photographs showing the rod of fibrous deposits synthesized at varied temperatures.

FIG. 18 is table showing the conditions of post-anneal.

FIG. 19 is TEM photograph showing the fibrous deposit after post-anneal.

FIG. 20 is comparison between the fibrous deposit synthesized from CO₂ and the carbon nanotube (CNT) synthesized by a conventional catalytic CVD using hydro-carbon gas.

FIG. 21 is the deposit obtained by plasma CVD followed by the post-anneal at 1203K (930 degrees Celsius).

FIG. 22 is the deposit obtained by plasma CVD followed by the post-anneal at 1253K (980 degrees Celsius).

FIG. 23 is TEM photograph showing the bottom and top of film obtained by the embodiment 4.

FIG. 24 is an explanation of the growth of film.

### BEST MODE FOR CARRYING OUT THE INVENTION

Hereafter, the detailed explanation of the operation performances of this invention is given by referring the figures. It is noted that the present invention is not limited to the experimental results and the examples of figures but alter and extend in various ways.

### Embodiment 1

First, the reaction device, which is the CO₂ recycling device described in embodiment 1, is explained. The substrate is thermally oxidized Si (001), the surface of which is vacuum-coated with Fe (purity 99.5%, a few nm thick) as catalyst.

The annealing conditions for thermal oxidation are as follows.
temperature: 700 degrees Celsius
time: 15 (min)
pressure: 15 (Pa)
carrier gas (H₂): 50 (sccm)

Next, carbon oxide gas is explained. As a sample of carbon oxide gas, the exhaust gas emitted from an actual vehicle powered by the 1.5 liter engine. The composition of this gas is shown below.

TABLE 1

| | |
|---|---|
| H₂0 | 10% |
| CO₂ | 14% |
| CO | 0.6% |
| HC (C₃H₆, C₃H₈) | 500 ppm |
| NO | 500 ppm |
| O₂ | 0.56% |
| N₂ | balance |

It is known that carbon nanotube can be synthesized from hydrocarbons as C₃H₆ and C₃H₈, which exist in the exhaust gas. The other gases that contain carbon are CO₂ and CO. Table 1 signifies that CO₂ is 20 times greater than CO.

From these gases, carbon structures such as carbon nanotube etc. were synthesized by microwave plasma CVD and thermal CVD.

Specifically, the exhaust gas is collected in a plastic bag, and the gas with H₂, which is carrier gas, is introduced to the microwave plasma CVD apparatus and thermal CVD apparatus in order to synthesize carbon nanotubes etc.

Figure depicts the schematic diagram of reaction device based upon microwave plasma CVD. The synthesis of nano-carbons was carried out in a quartz tube with a diameter of 18 mm and a length of 800 (mm), the outer periphery of which is equipped with microwave oscillator and muffle furnace. In the quartz tube, plasma and decomposition of gases occur to deposit nano-carbons on the substrate placed in the quartz tube. The microwave is a commercially available magnetron fitted to microwave oven, and the oscillating frequency is 2.45 GHz and the maximum output power is 500 W.

A mass-flow controller controls the flow rate of material gas and carrier gas supplied from a gas cylinder or a plastic bag, and the depressurized gases are introduced to the quartz tube by a rotary pump. A DC power supply is used to apply bias to a substrate.

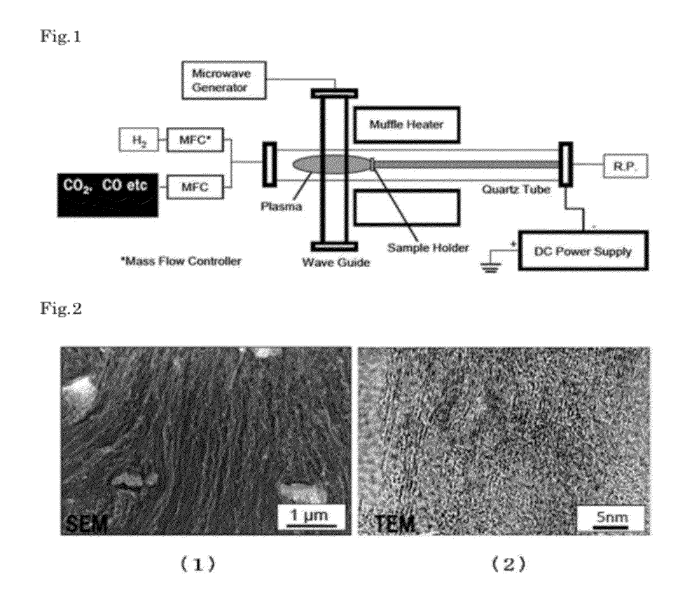

The thermal CVD is a simple device without having the microwave plasma generator in FIG. 1. However, the controlling temperature of substrate in the quartz tube or carrier gas sometimes is different from those of plasma CVD.

The conditions for microwave plasma CVD are as follows.
temperature: 700 degrees Celsius
time: 3 (min)
pressure: 100 (Pa)
carrier gas (H₂) flow: 50 (sccm)
collected exhaust gas: 20 (sccm)

The conditions for thermal CVD are as follows.
temperature: 700 degrees Celsius
time: 3 (min)
pressure: 100 (Pa)
carrier gas (H₂) flow: 50 (sccm)
collected exhaust gas: 20 (sccm)

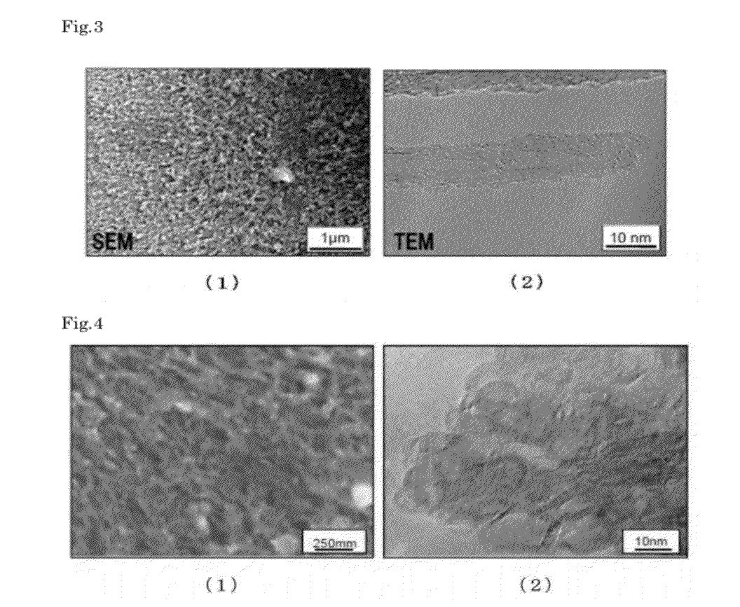

Nano-carbons formed on the substrate were investigated by transmission electron microscopy (TEM) and scanning electron microscopy (SEM). The results are indicated in FIGS. 2 and 3.

FIG. 2 shows the nano-carbon structure synthesized by microwave plasma CVD. FIG. 2(1) is a SEM photograph, while FIG. 2(2) is a TEM photograph. From the TEM photograph in FIG. 2(2), multi-walled carbon nanotubes as well as nano-fiber with relatively large diameter and amorphous-like derivatives are observed.

FIG. 3 shows the nano-carbon structure synthesized by microwave plasma CVD. FIG. 3(1) is a SEM photograph, while FIG. 3(2) is a TEM photograph. From the TEM photograph in FIG. 3(2), multi-walled carbon nanotubes are observed.

In addition, it was found that the nano-carbon structure was synthesized from carbon dioxide, CO₂, contained in exhaust gas. The conditions for micro-plasma CVD are as follows.
temperature: 700 degrees Celsius
time: 3 (min)
pressure: 100 (Pa)
carrier gas Ar: 15 (sccm), H₂: 50 (sccm)
carbon dioxide (CO₂): 5 (sccm)

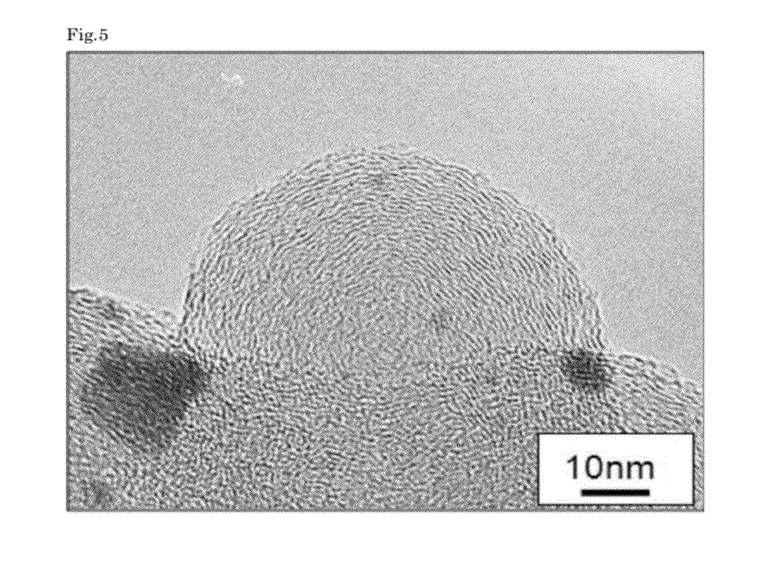

The experimental results of nano-carbon structures shown in FIGS. 4 and 5 are obtained from solely CO₂ in the exhaust gas.

FIG. 4(1) is a scanning electron micrograph, while FIG. 4(2) and FIG. 5 are transmission electron micrographs. From FIG. 4(2), nearly onion-like structure was found.

It is possible that carbon onion is generated from CO₂, because carbon onion has low aspect ratio compared with carbon nanotube. From TEM photograph in FIG. 5, the synthesis of carbon onion is recognized.

The reduction of CO₂ emission is the great problem for the industries where they emit CO₂, such as heavy industries and steel making companies. By placing the present reaction device at the top of chimney, carbon nano-structures can be collected at a certain interval.

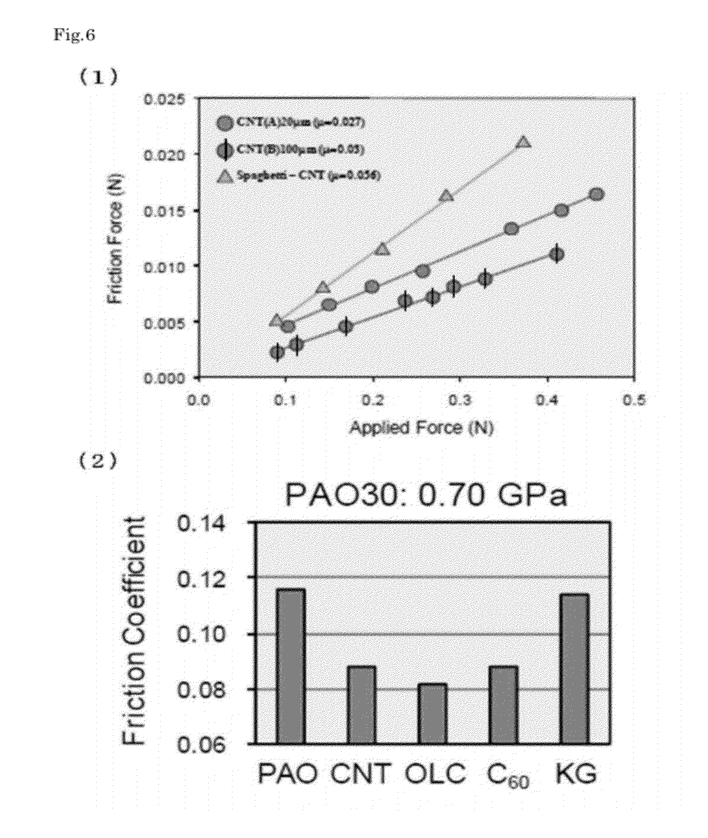

Especially, carbon onions as well as carbon nanotubes are good lubricant additive (for example, only 0.1 wt % addition can reduce friction to 1/100), see FIG. 6(2), and thus this invention contributes not only to atmosphere/eco problems of reducing CO₂ emission but also to save materials/save energy effect by lowering friction.

CO₂ may be emitted by utilizing nano-carbons as lubricant additives, but zero carbon offset is possible by re-synthesizing nano-carbons again from those CO₂.

In view of the fuel consumption, it is not advantageous to supply energy from automobile engine to this reaction device. However, the temperature near the front-muffler is around 700 degrees Celsius. Therefore, the heat generated near the front-muffler can be used as a heat source for this reaction device.

### Embodiment 2

In the embodiment 2, the direction of gas introduction to the reaction device wad made opposite to the embodiment 1, that is, the material gas was first introduced to the muffle furnace, then to the substrate, and finally to microwave oscillator where the plasma generates.

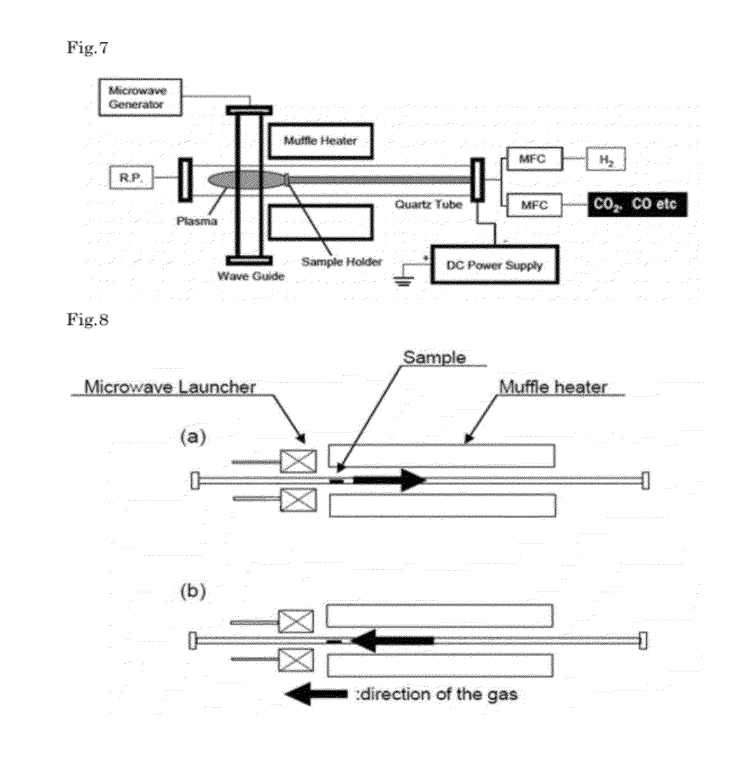

FIG. 7 shows a schematic diagram of the reaction device which utilizes microwave plasma CVD. FIG. 8 compares two devices described in embodiments 1 and 2. As indicated in FIG. 8(a), in the case of embodiment 1, material gas from gas cylinder is controlled at the mass-flow controller, passes through microwave oscillator, and reaches substrate after becoming plasma. In contrast, as indicated in FIG. 8(b), the direction of gas flow in embodiment 2 is opposite. The material gas from gas cylinder passes through muffle furnace and substrate, and reaches microwave oscillator where plasma generates.

The conditions for microwave plasma CVD in embodiment 2 are as follows.
temperature: 700 degrees Celsius
time: 10 (min)
pressure: 100 (Pa)
carrier gas (H₂) flow: 50 (sccm)
CO₂ gas: 20 (sccm)

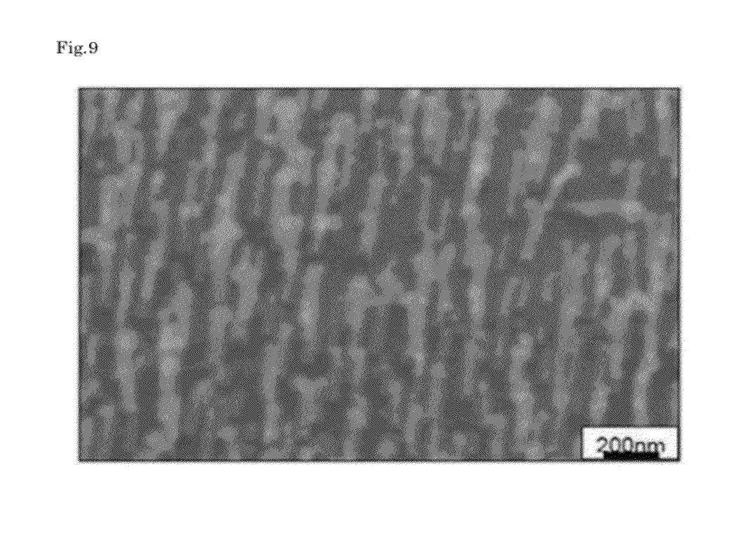

Surface appearance of nano-carbon structure synthesized by microwave plasma CVD in embodiment 2 is shown in FIG. 9.

As indicated in FIG. 9, synthesized nano-carbon has a fibrous structure, and precipitates very compact over the entire area of substrate. The diameter of fibrous deposits is a few tens of nm, and the length is a few hundreds of nm. Moreover, this fibrous structure tends to have orientation, and distributes entire area of substrate surface.

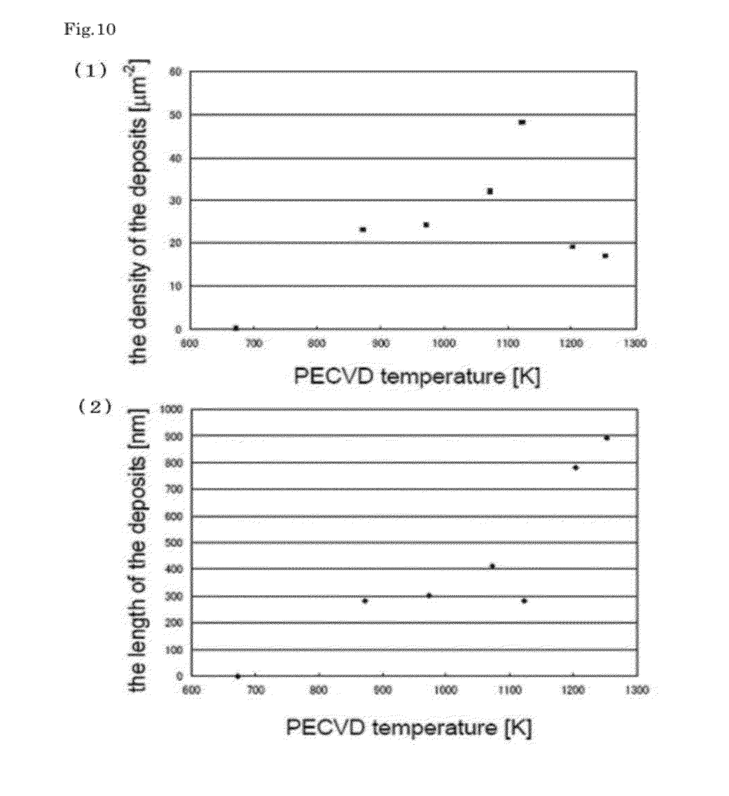

By changing only temperature in the furnace, while unchanging the size and the location of substrate, introduction gas, flow rate and pressure, the density and length of synthesized fibrous deposits was measured. The results are shown in FIG. 10.

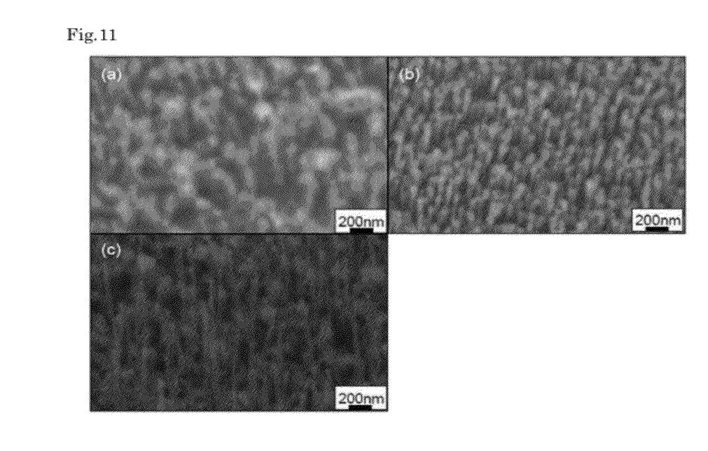

The density of fibrous deposits becomes highest at the temperature of 1123K (850 degrees Celsius), and the length increases up to 1073K (800 degrees Celsius), decreases at 1123K (850 degrees Celsius), and then increases again in accordance with the increase of temperature. FIG. 11 shows surface appearance of fibrous material synthesized at 1073K (800 degrees Celsius), 1123K (850 degrees Celsius) and 1203K (930 degrees Celsius).

As is clear from FIG. 11, the fibrous deposits synthesized at 1123K (850 degrees Celsius) at which temperature the density becomes largest while the length shortest, grows very compact (FIG. 11(b)). At 1203K (930 degrees Celsius), the length of fiber is very long at about 1 μm, while the density appears to slightly small. In addition, individual fibrous deposits align perpendicular to the substrate, grow straight and are highly oriented.

In the case of furnace temperature of 1203K (930 degrees Celsius) shown in FIG. 11(c), non-oriented fibrous deposits are observed at the bottom of long fibrous deposits. Non-oriented ones at the bottom of long fibers cannot be counted clearly, and they were omitted for the density calculation, and thus underestimation may lead to the lowered density.

It has been made clear, from the embodiment 2, that very long oriented fibrous deposits are synthesized with considerable high density. The plasma CVD in the embodiment 2 is useful for the synthesis of fibrous deposits, not only because the high densities, which relates to the efficiency of processing, is required, but also because long and high orientation, and reduced energy are required just like the same as in the case of carbon nanotubes.

Next, the characteristics of structure of fibrous deposits are explained. To make clear the inner structure, fibrous deposits were removed mechanically from the substrate and observed by TEM.

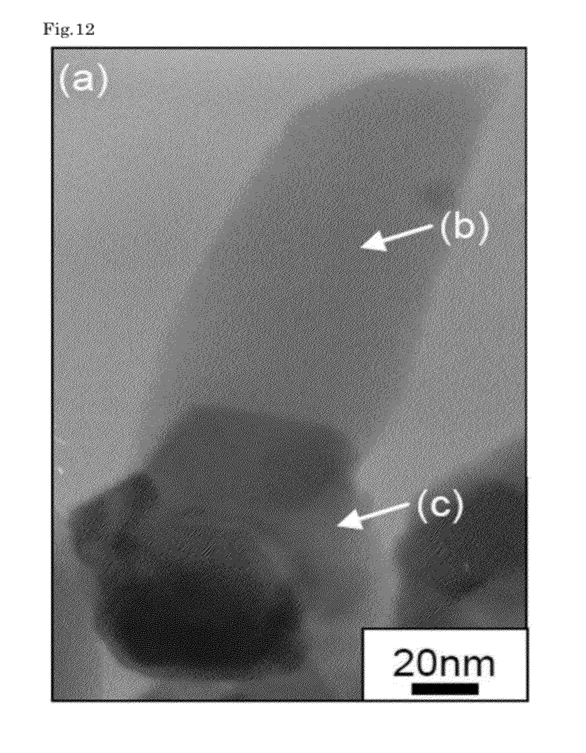

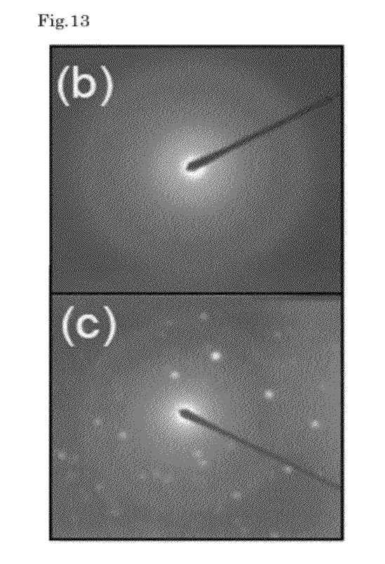

As shown in FIG. 12, the fibrous deposit has a very unique structure consisting of rod which has cylinder with a diameter of 80 nm and a length of a few hundreds of nm (arrow in (b)) and of chunk with a size of about 100 nm (arrow in (c)). The chunk is surrounded by a material with low crystallographic structure. Electron diffraction patterns from the rod and chunk are shown in FIGS. 13(b) and (c), respectively.

The electron diffraction pattern from the rod (FIG. 13(b)) does not show the diffraction ring, and thus the rod has an amorphous structure as estimated from the bright field image. The electron diffraction pattern from the chunk (FIG. 13(c)) shows aligned bright spots, and TEM photograph showed regular straight lines. This implies that the chunk contains crystallographic structure, and it is estimated that the chunk consists of catalytic Fe.

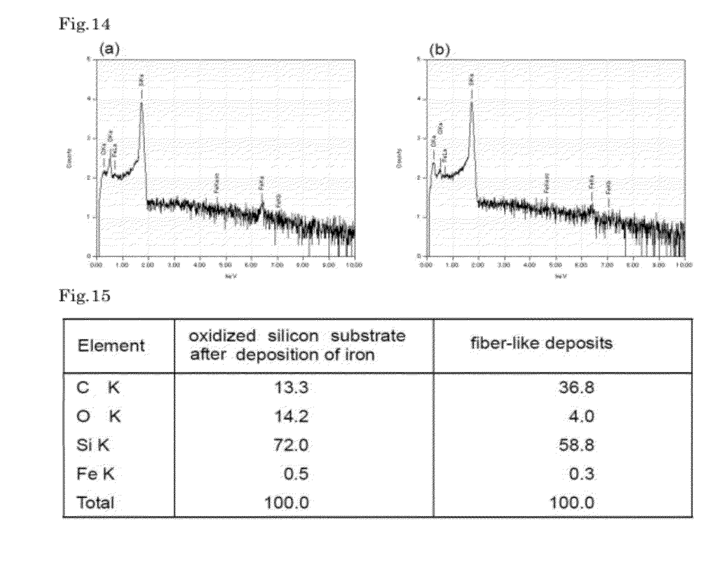

The composition of fibrous deposits was analyzed by EDS, and the results are shown in FIG. 14.

FIG. 14(a) shows the EDS spectra from the thermally oxidized substrate on which surface Fe was coated. FIG. 14(b) is the EDS spectra from the fibrous deposit synthesized at a furnace temperature of 973K (700 degrees Celsius).

FIG. 14(b) clearly shows the peak at CK-α (Alpha). The quantitative analytical results are shown in FIG. 15.

13.3% carbon on the thermally oxidized Si substrate on which Fe was coated is considered as contamination in air. The carbon content in fibrous deposits is high at 36.8% and greater than that before plasma CVD. Obviously, fibrous deposits are carbonaceous material, and the rod part, which is the major structure of fibrous deposits, is possibly an amorphous carbon.

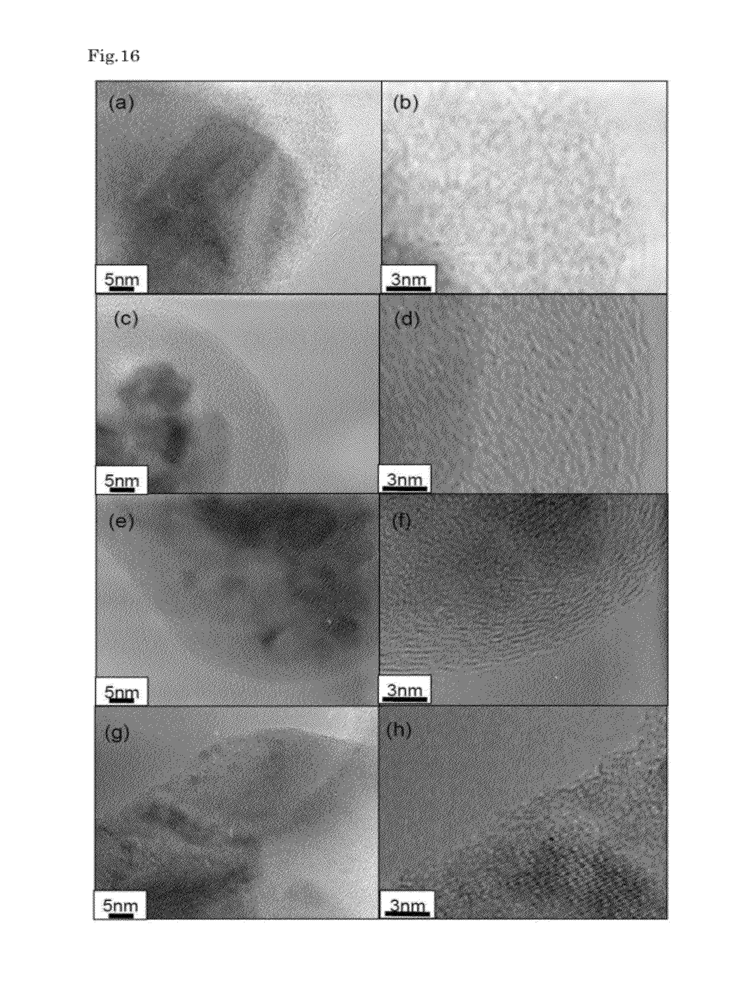

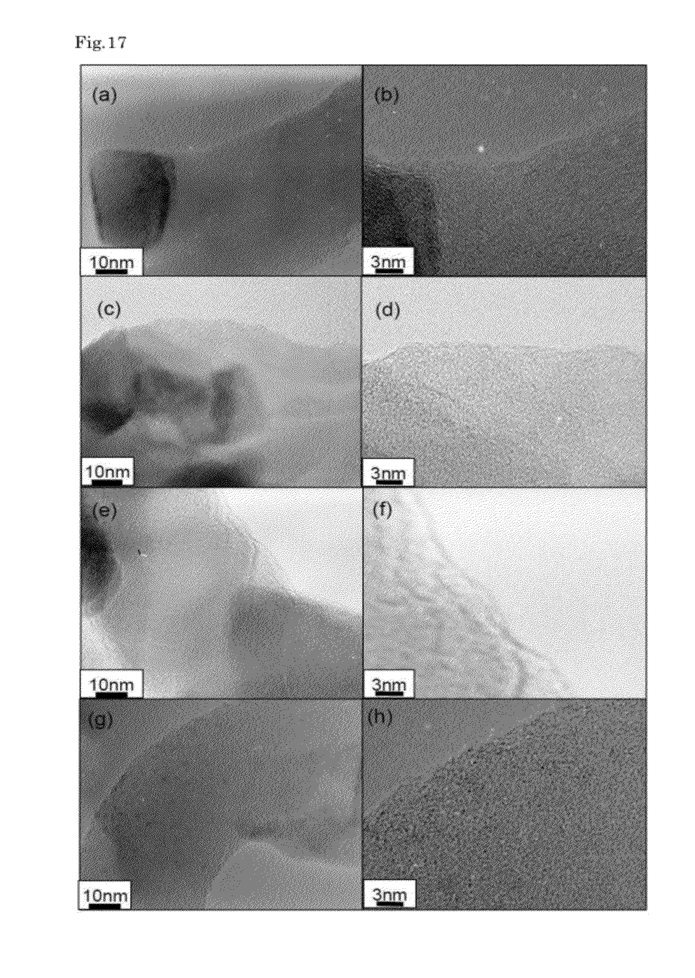

This fibrous deposit exhibits the difference structure depending on furnace temperature. TEM photographs of the chunk and rod for fibrous deposits synthesized at different temperatures are shown in FIG. 16 and FIG. 17, respectively.

FIGS. 16(a) and (b), (c) and (d), (e) and (f), (g) and (h) are TEM photographs of chunk part obtained at the furnace temperatures of 873K (600 degrees Celsius), 973K (700 degrees Celsius), 1123K (850 degrees Celsius) and 1203K (930 degrees Celsius).

FIGS. 16(b), (d), (f) and (h) are magnified pictures of FIGS. 16(a), (c), (e) and (g).

The chunk of all specimens consists of catalytic metal and the surrounding part. The structure of surrounding part shows clear straight lines up to 1123K (850 degrees Celsius) with respect to the increase in temperature. In contrast, the specimen prepared at 1203K (930 degrees Celsius) is very thin and shows no straight lines.

FIGS. 17(a) and (b), (c) and (d), (e) and (f), (g) and (h) are TEM photographs of rod part obtained at the furnace temperatures of 873K (600 degrees Celsius), 973K (700 degrees Celsius), 1123K (850 degrees Celsius) and 1203K (930 degrees Celsius). FIGS. 17(b), (d), (f) and (h) are magnified pictures of FIGS. 17(a), (c), (e) and (g).

The rod of fibrous deposits did not show any changes in spite of the difference in furnace temperatures but stayed amorphous. Unlike the chunk part, the structure of rod is not affected by the furnace temperature.

(Graphitization of Fibrous Deposits)

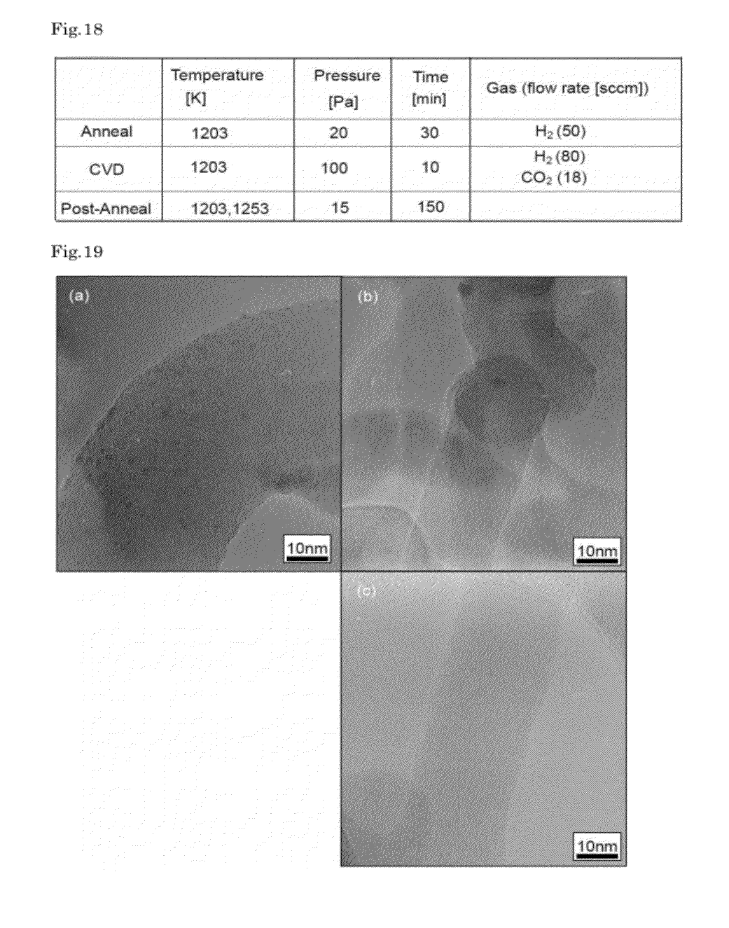

Graphitization of fibrous deposits was attempted by processing the temperature and time in the furnace (post-anneal) after synthesizing fibrous deposits from CO₂, without breaking the vacuum. The fibrous deposit was synthesized by plasma CVD at 1203K (930 degrees Celsius). Post-anneal was carried out at 1203K (930 degrees Celsius) and 1253K (980 degrees Celsius). The conditions for post-anneal are described in FIG. 18. The TEM photograph after post-anneal is shown in FIG. 19.

FIG. 19(a) shows the TEM photograph of rod part synthesized at 1203K (930 degrees Celsius). FIGS. 19(b) and (c) are those taken after the post-anneal at 1203K (930 degrees Celsius) and 1253K (980 degrees Celsius). Graphite structures were not found for all the specimens, and thus the effect of post-anneal was not recognized.

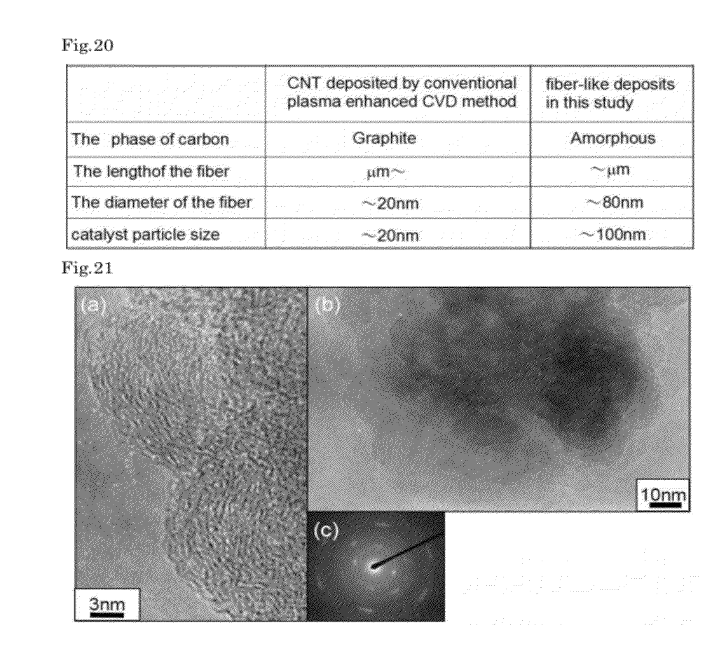

FIG. 20 compares fibrous deposits made from CO₂ and carbon nanotube (CNT) prepared from hydrocarbons by catalytic CVD. The rod of synthesized fibrous deposits had larger diameter and short length with amorphous structure.

(Synthesis of OLC-Like Material)

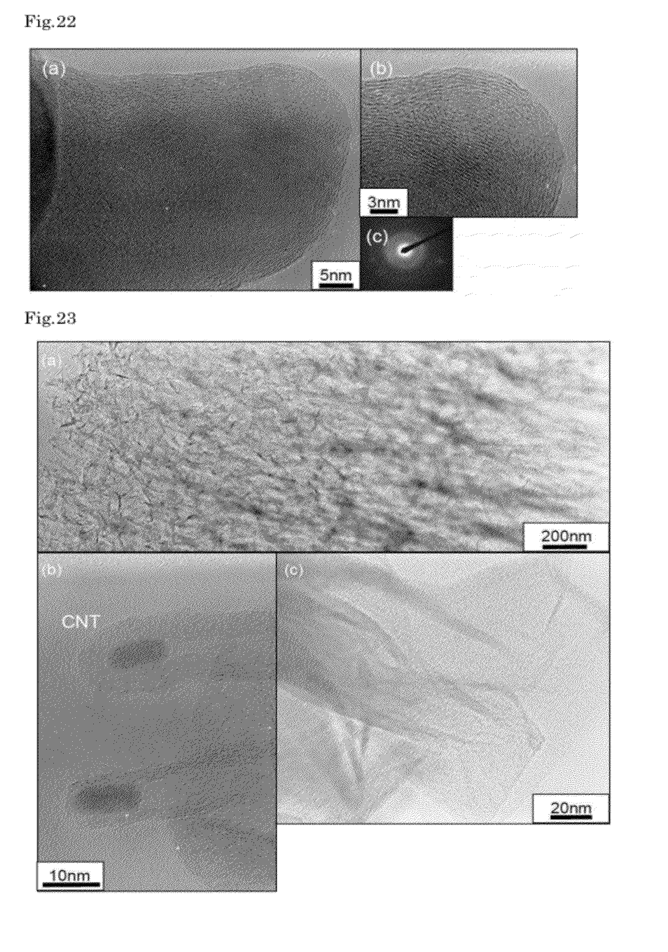

Post-anneal provided round shaped materials from fibrous deposits as shown in FIGS. 21 and 22. FIG. 21 shows the deposit obtained after plasma CVD and post-anneal at 1203K (930 degrees Celsius). This deposit appears the agglomeration (see FIG. 21 8b)) of spherical particles (see FIG. 21(a)) with characteristic stripe pattern. The electron diffraction pattern in FIG. 21(c) exhibits a clear diffraction ring at 0.325 nm. This value is very close to the interspacing of graphite, 0.335 nm, and thus this material is made of carbon and has a round shape which resembles OLC.

FIG. 22 shows the deposit obtained after post-anneal at 1253K (980 degrees Celsius). FIG. 22 shows the stripe pattern, characteristic to graphite, as well. FIG. 22(c) signifies the hallow diffraction ring at 0.35 nm interspacing. It can be seen in FIG. 22(b) that the stripe pattern forms spherical structure in an inner part. This implies that the deposit resembles OLC.

It has been made clear that the agglomerate with the structure of graphite is synthesized by post annealing at above 1073K (800 degrees Celsius), e.g., 1203K (930 degrees Celsius) and 1253K (980 degrees Celsius). The amount of observed agglomerate is smaller than those of amorphous fibers, and it is not easy to measure the change depending on anneal temperatures.

In contrast, TEM photograph in FIG. 22 shows clearer stripe pattern than those in FIG. 21, indicating increased crystallography due to annealing.

As stated, DLC-like graphite agglomerates did not exist before the post annealing but existed after post annealing, and no gas supply was made. Thus, the agglomerate received carbon from amorphous carbon rod. It is possible that the amorphous carbon in the rod of fibrous deposit transformed into graphite during post annealing and that the shape turned into spherical graphite. It is noted that the OLC-like graphite is successfully synthesized by the method completely different from conventional ones using especially CO₂, though at present the amount is not quite large.

(Solidifying Rate of CO₂)

This invention described in the embodiments 1 and 2 proposes new CO₂ recycling method and device that enable the synthesis of highly value-added products with aiming the synthesis of advanced carbonaceous materials.

The synthesis of nano-carbons was already explained. Especially in the embodiment 2, the synthesis of fibrous amorphous carbon was successfully made over the entire area of substrate. The solidifying rate of CO₂ into the form of fibrous deposits is to be explained.

$${m}_{0} = \frac{Q \times {10}^{- 3} \times t}{22.4} \times 12 \qquad [ Equation 1 ]$$

In equation1, m₀ became 0.107g at CO₂ flow rate of 20 (sccm) and for 10 (min) CVD. The mass of carbon deposited as a fibrous material m can be written as shown in equation 2, when the length of fiber deposit is 1 (nm), diameter D (nm), density of precipitation d_{d} (micrometer⁻²), area of substrate S (cm²), and the density of amorphous carbon d_{c} (g/cm³).

$$m = \frac{1}{4} {π ( D \times {10}^{- 7} )}^{2} \times l \times {10}^{- 7} \times {d}_{c} \times {d}_{d} \times {10}^{8} \times S \qquad [ Equation 2 ]$$

In the present embodiment, length l=900 (nm), diameter was D=45 (nm), precipitation density d_{d}=20 (micrometer⁻²), and the area of substrate S=0.5 (cm²). Here, the density d_{d} denotes the true density, and therefore the apparent density (or bulk density) of amorphous carbon in the literatures cannot be applied in the present embodiment. In addition, the ratio of sp² and sp³ bonds and the content of hydrogen are unknown, and the theoretical calculation is not possible. From these viewpoints, it was assumed that the true density does not exceed that of diamond 3.52 (g/cm³), i.e., dc=1.0 to 3.0 (g/cm³). The results of calculation was m=1.43×10⁻⁶ (g) to 4.29×10⁻⁶ (g).

The ratio of mass of carbon precipitated as fibrous deposits s can be given by the following equation 3.

$$s = \frac{m}{{m}_{0}} \qquad [ Equation 3 ]$$

The calculation using equation 3 leads to s=1.34×10⁻⁵ to 4.00×10⁻⁵. As shown in embodiment 2, this value was obtained by letting the gas pass through the furnace, reach the microwave oscillator and then plasma-vapored. In the present embodiment, the area of substrate was limited to S=0.5 (cm²) due to the device configuration, but a scale-up of the device can enlarge the area to a certain extent, and it is easily understood that S increases with an increase of area. Moreover, there will be a method to optimize the solidifying ratio by adjusting the flow rate of gas.

For example, the use of ten times larger substrate and a half gas flow are able to increase the s value up to 0.1. As is obvious, the improvement of s by synthesizing larger amount of fibrous deposits is an important factor to raise the value of deposits as an advanced carbon material.

### Embodiment 3

(Reduction of CO₂)

In embodiment 3, the results of measurement of CO₂ reduction using the plasma CVD are shown. The thermally oxidized Si wafer onto which Fe is vacuum coated is used as a substrate, which is the same in embodiment 2.

The conditions for microwave plasma CVD in embodiment 3 are as follows.
temperature: 980 degrees Celsius
time: 7 (min)
pressure: 100 (Pa)
carrier gas (H₂) flow: 95 (sccm)
CO₂ gas: 24 (sccm)

The sampling of CO₂ at the inlet was first carried out using a scroll vacuum pump, and the amount of CO₂ was measured by a CO₂ detector. The same procedures was carried out for CO₂ gas at the outlet, that is, the gas passed through muffle furnace, substrate and microwave plasma CVD device.

Using microwave plasma CVD, the CO₂ amount at the outlet was 4.0%, while that at inlet was 15.8%.

This signifies that the CO₂ reduction rate by using the microwave CVD is 74.7%. This reduction of CO₂ can be achieved by solidifying carbon on the surface of substrate and water vapor formation due to decomposition of CO₂.

### Embodiment 4

(Synthesis from CO)

In embodiment 4, the results of synthesis of carbonaceous materials from CO using the plasma CVD are shown. The thermally oxidized Si wafer onto which Fe is vacuum coated is used as a substrate.

The conditions for microwave plasma CVD in embodiment 4 are as follows.
temperature: 700 degrees Celsius
time: 10 (min)
pressure: 100 (Pa)
carrier gas (H₂) flow: 37 (sccm)
CO₂ gas: 37 (sccm)

From the microwave plasma CVD in the embodiment 4, the irregularly aligned asperities were found on the surface of substrate in the form of continuous film with a few micrometer thick. FIG. 23 depicts the TEM photograph of the cross section of this film, the TEM sample of which is removed by a mechanical scratching. The lower left in FIG. 23 was taken from the bottom of the film, while the lower right the top of the film.

Both from the surface appearance and the cross sectional view in FIG. 23(c), irregular shaped film-like graphite is formed on the top. At the bottom of film shown in FIG. 23(b), CNT, which is a hollow tube of graphite with metal particle. Thus, this film has a very unique structure with CNT at the bottom and graphite film at the top. It is estimated that the graphite film is carbon nano-flake (CNF), which is the quasi-two dimensional graphite.

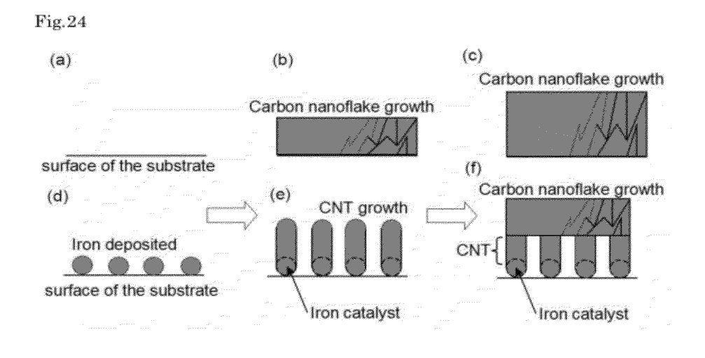

Carbon nano-flakes are found for the substrate without catalytic Fe particles. A model shown in FIG. 24 explains well the growth of this film.

It is explained why CNFs are formed on the surface without catalytic Fe. CNT grows by the precipitation of carbon in the form of tube through the catalytic Fe particle, whereas CNFs grow in a planar structure without fixed orientation. When carbon atoms are supplied from gas phase on the surface without such influential factors as catalytic Fe particles, amorphous carbons and irregularly stacked two dimensional graphite structure were synthesized.

In addition, etching by hydrogen in the plasma removed amorphous carbons, and random array of flake created CNFs. This leads to the synthesis of CNFs at the surface without catalyst.

The CNT/CNF composite shown in FIG. 23 can be synthesized first by the growth of CNT (FIG. 24 (e)) from the Fe catalyst (FIG. 24(d)), and then by the growth of CNF at the top of CNT where catalysts seldom exist, and thus the composite film was synthesized (FIG. 24 (f)).

### INDUSTRIAL APPLICABILITY

This invention is effective in reducing CO₂ emitted from engines of auto-mobiles, ships etc, and for example, the device in this invention can be loaded on automobile mufflers to reduce CO₂. This invention contributes to the clean environment of social structure.

### DESCRIPTION OF SYMBOLS

1 Reaction Device

2 Substrate

3 Catalytic Layer

4 Reaction Tube

5 Gas Introduction Unit

6 Heater Unit

7 Power Supply Unit

8 Microwave Generator

9 Microwave Guide

10 Plasma Region

1-20. (canceled)

21. A CO₂ recycling method comprising at least one of the following:
synthesizing multi-walled carbon nanotubes, carbon onions and/or nano-carbons with microwave plasma CVD using COₛ in carbon oxide gases;
synthesizing multi-walled carbon nanotubes, carbon onions and/or nano-carbons with thermal CVD using CO₂ in carbon oxide gases.

22. The CO₂ recycling method according to claim 21, wherein said carbon oxide gases comprise automobile exhaust gases, and wherein the method further comprises adding synthesized multi-walled carbon nanotubes, carbon onions and/or nano-carbons to a base lubricant, whereby lowering engine piston friction is adapted for lowering fuel consumption.

23. The CO₂ recycling method according to claim 21, wherein a carrier gas of said carbon oxide gases is H₂.

24. The CO₂ recycling method according to claim 21, wherein the pressure range during the CVD (microwave plasma CVD or thermal CVD) is 100 to 200 Pa.

25. The CO₂ recycling method according to claim 21, wherein the temperature range during the CVD (microwave plasma CVD or thermal CVD) is 800 to 980 degrees Celsius.

26. The CO₂ recycling method according to claim 21, wherein the method comprises synthesizing multi-walled carbon nanotubes, carbon onions and/or nano-carbons with microwave plasma CVD using COₛ in carbon oxide gases.

27. The CO₂ recycling method according to claim 21, wherein the method comprises synthesizing multi-walled carbon nanotubes, carbon onions and/or nano-carbons with thermal CVD using CO₂ in carbon oxide gases.

28. A CO₂ recycling device for synthesis of multi-walled carbon nanotubes, carbon onions and/or nano-carbons from CO₂ in automobile exhaust gases using CVD, the device comprising:
a substrate onto which Fe is coated as a catalyst;
a heating means that heats up the substrate; and
a gas introduction means that introduces carbon oxide gases to the substrate.

29. The CO₂ recycling device of claim 28, wherein said substrate is placed at an inside wall of an automobile muffler, and said heating means comprises automobile exhaustion heat.

30. The CO₂ recycling device of claim 28, wherein said substrate is placed at one or more of the following locations:
an air-conditioning exhaust duct;
an air-conditioning filter;
a tunnel ventilation device;
a ship exhaust duct;
a locomotive exhaust duct;
a factory exhaust duct;
an express highway wall surface;
an express highway signboard;
a road tunnel wall surface;
a road tunnel signboard.

31. The CO₂ recycling device of claim 28, wherein said heating means is able to heat the substrate to a temperature in the range 800 to 980 degrees Celsius.

32. The CO₂ recycling device of claim 28, wherein the device is characterized by the synthesis of multi-walled carbon nanotubes, carbon onions and/or nano-carbons from CO₂ in automobile exhaust gases using microwave plasma CVD, and wherein the device further comprises:
a microwave plasma generator means that creates microwave plasma at the substrate surface; and
a power supply means that supplies electric power to the microwave generator means.

33. The CO₂ recycling device of claim 32, wherein said substrate is placed at an inside wall of an automobile muffler, and said heating means comprises automobile exhaustion heat.

34. The CO₂ recycling device of claim 32, wherein said substrate is placed at one or more of the following locations:
an air-conditioning exhaust duct;
an air-conditioning filter;
a tunnel ventilation device;
a ship exhaust duct;
a locomotive exhaust duct;
a factory exhaust duct;
an express highway wall surface;
an express highway signboard;
a road tunnel wall surface;
a road tunnel signboard.

35. The CO₂ recycling device of claim 32, wherein said heating means is able to heat the substrate to a temperature in the range 800 to 980 degrees Celsius.

36. The CO₂ recycling device of claim 32, wherein said substrate is located at a distance from the microwave plasma generator and said gas introduction means has a direction whereby gas goes along the microwave plasma generator means after being heated by said heating means.

37. The CO₂ recycling device of claim 28, wherein the device is characterized by the synthesis of multi-walled carbon nanotubes, carbon onions and/or nano-carbons from CO₂ in automobile exhaust gases using thermal CVD.
